(19) United States
(12) Patent Application Publication
(10) Pub. No.: US 2009/0273962 A1
(43) Pub. Date: Nov. 5, 2009

(54) FOUR-TERMINAL MULTIPLE-TIME PROGRAMMABLE MEMORY BITCELL AND ARRAY ARCHITECTURE

(75) Inventor: Robertus Petrus van Kampen, S-Hertogenbosch (NL)

Correspondence Address: PATTERSON & SHERIDAN, L.L.P., 3040 POST OAK BOULEVARD, SUITE 1500, HOUSTON, TX, 77056, US

(73) Assignee: CAVENDISH KINETICS INC., San Jose, CA (US)

(21) Appl. No.: 12/433,027

(22) Filed: Apr. 30, 2009

Related U.S. Application Data
(60) Provisional application No. 61/126,149, filed on Apr. 30, 2008.

(51) Int. Cl. G11C 5/06; G11C 11/34; G11C 7/00

(52) U.S. Cl. 365/72; 365/174; 365/189.011

(57) ABSTRACT

Embodiments disclosed herein relate to a non-volatile memory bitcell and arrays thereof, methods of detecting whether the bitcell is in a programmed state, methods of detecting whether the bitcell is in an erased state, methods of setting the bitcell in a programmed state and methods of setting the bitcell in an erased state. The non-volatile memory bitcell may be a four terminal bitcell. The bitcell may have a pull-up electrode, a pull-down electrode, a cantilever electrode and a contact electrode. An NMOS transistor may be coupled to the contact electrode. Depending upon the orientation of the word line, the current through the bitcell may be measured on the bitline, the data line or the pull-down electrode.

### CROSS-REFERENCE TO RELATED APPLICATIONS

This application claims benefit of U.S. Provisional Patent Application Ser. No. 61/126,149 (CK054L), filed Apr. 30, 2008, which is herein incorporated by reference.

### BACKGROUND OF THE INVENTION

1. Field of the Invention

Embodiments disclosed herein generally relate to the field of micro-electromechanical multiple-time programmable memory bitcells.

2. Description of the Related Art

Typical non-volatile memory architectures used in such devices as Erasable Programmable Read-Only Memory (EPROM) are often complicated and need complex drive and power circuitry.

Multiple-Time Programmable (MTP) memory bitcells comprising bistable cantilevers have been developed in order to reduce the drive and power circuitry needed to build arrays of non-volatile memory. Such devices have advantages when compared to traditional semiconductor-based memory cells in that they can operate as non-volatile memories without the need for supporting power supplies.

However, such devices also have disadvantages in that control of their programming can be complicated. Moreover, the switching speeds of these bistable cantilevers will depend on the voltage being applied between the cantilever and one of two activation electrodes. A higher voltage will create a larger electrostatic force, thereby urging the electrode towards the activation terminal more rapidly. When the cantilever contacts the activation terminal, a current will pass from the cantilever to the activation electrode. Accordingly, if the voltage applied to the activation electrode is high, the resulting current will also be high.

High current bridging the cantilever and the activation electrode can cause damage to the electrode and/or the activation electrode. In some circumstances, the current can weld these two elements together such that further movement and programming is not possible, thereby effectively destroying the memory bitcell.

Accordingly, there is a clear need for a simple multiple-times programmable memory bitcell and array architecture which prevents excessive current transfer between the cantilever and the activation electrodes while ensuring reliable operation.

### SUMMARY OF THE INVENTION

As will be appreciated, the present invention provides several advantages over the prior art. For example, because the bitcell of the present invention comprises four terminals, the voltage needed to move the bistable cantilever from a first position to a second position will not induce current though the cantilever. Moreover, because the architecture of the present invention uses only a single selection transistor, the resulting device is simpler and less expensive to manufacture than existing devices.

Embodiments disclosed herein relate to a non-volatile memory bitcell and arrays thereof, methods of detecting whether the bitcell is in a programmed state, methods of detecting whether the bitcell is in an erased state, methods of setting the bitcell in a programmed state and methods of setting the bitcell in an erased state. The non-volatile memory bitcell may be a four terminal bitcell. The bitcell may have a pull-up electrode, a pull-down electrode, a cantilever electrode and a contact electrode. An NMOS transistor may be coupled to the contact electrode. Depending upon the orientation of the word line, the current through the bitcell may be measured on the bitline, the data line or the pull-down electrode.

In one embodiment, a non-volatile memory bitcell is disclosed. The bitcell may include a pull-up electrode covered in electrically insulating material, a pull-down electrode and a contact electrode disposed adjacent the pull-down electrode. The bitcell may also include a cantilever electrode connected to a bi-stable cantilever positioned between the pull-up electrode and the contact electrode. The bi-stable cantilever is movable between a position in contact with the contact electrode and a position in contact with the insulating material covering the pull-up electrode.

In another embodiment, a memory array is disclosed. The memory array may include a plurality of non-volatile memory bitcells. Each of the bitcells may include a pull-up electrode covered in electrically insulating material, a pull-down electrode and a contact electrode disposed adjacent the pull-down electrode. The bitcell may also include a cantilever electrode connected to a bi-stable cantilever positioned between the pull-up electrode and the contact electrode. The bi-stable cantilever is movable between a position in contact with the contact electrode and a position in contact with the insulating material covering the pull-up electrode. The bitcell may also include a transistor coupled to the contact electrode, wherein a drain electrode of the transistor is coupled to the contact electrode.

In another embodiment, a method of detecting the state of a non-volatile memory array bitcell. The non-volatile memory bitcell comprises a pull-up electrode covered in electrically insulating material, a pull-down electrode and a contact electrode disposed adjacent the pull-down electrode. The bitcell also includes a cantilever electrode connected to a bi-stable cantilever positioned between the pull-up electrode and the contact electrode. The bi-stable cantilever is movable between a position in contact with the contact electrode and a position in contact with the insulating material covering the pull-up electrode. The bitcell also includes a transistor coupled to the contact electrode, wherein a drain electrode of the transistor is coupled to the contact electrode. The method includes applying a voltage to either a bitline coupled to the cantilever or a data lines coupled to the drain electrode of the transistor and sensing the current in either the bitline or the data line.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 represents a schematic representation of a Multiple-Time Programmable bitcell.

FIG. 2 represents a state diagram of the device of FIG. 1.

FIG. 3 represents a bitcell in accordance to one embodiment of the present invention.

FIGS. 4a-4c represent three separate further embodiments of bitcells in accordance with the present invention.

FIG. 5 represents drive signals applied to the devices of FIG. 3 and FIGS. 4a-4c, in the case of a hot-switched implementation.

FIGS. 6a-6c represent three further separate embodiments of hot-switched bitcells in accordance with the present invention.

FIG. 7 represents drive signals applied to the devices of FIG. 3 and FIGS. 4a-4c for a non-hot-switched implementation in accordance with the present invention.

FIGS. 8a-8d represent four further separate embodiments of non-hot-switched implementations of the present invention.

FIG. 9 represents a multiple-time programmable memory array architecture in accordance with one embodiment of the present invention.

FIG. 10 represents a multiple-time programmable memory array architecture in accordance with another embodiment of the present invention.

FIG. 11 represents a multiple-time programmable memory array architecture in accordance with another embodiment of the present invention.

FIG. 12 represents a multiple-time programmable memory array architecture in accordance with another embodiment of the present invention.

FIG. 13 represents a schematic view of two different implementations of a read operation of a bitcell in accordance with the present invention.

FIG. 14 represents a timing diagram of the various signals during the read operations in accordance with the implementations of FIG. 13.

FIG. 15 represents a first block architecture for programming and erasing bitcells in accordance with the present invention.

FIG. 16 represents another block architecture for programming and erasing bitcells in accordance with the present invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments disclosed herein relate to a non-volatile memory bitcell and arrays thereof, methods of detecting whether the bitcell is in a programmed state, methods of detecting whether the bitcell is in an erased state, methods of setting the bitcell in a programmed state and methods of setting the bitcell in an erased state. The non-volatile memory bitcell may be a four terminal bitcell. The bitcell may have a pull-up electrode, a pull-down electrode, a cantilever electrode and a contact electrode. An NMOS transistor may be coupled to the contact electrode. Depending upon the orientation of the word line, the current through the bitcell may be measured on the bitline, the data line or the pull-down electrode.

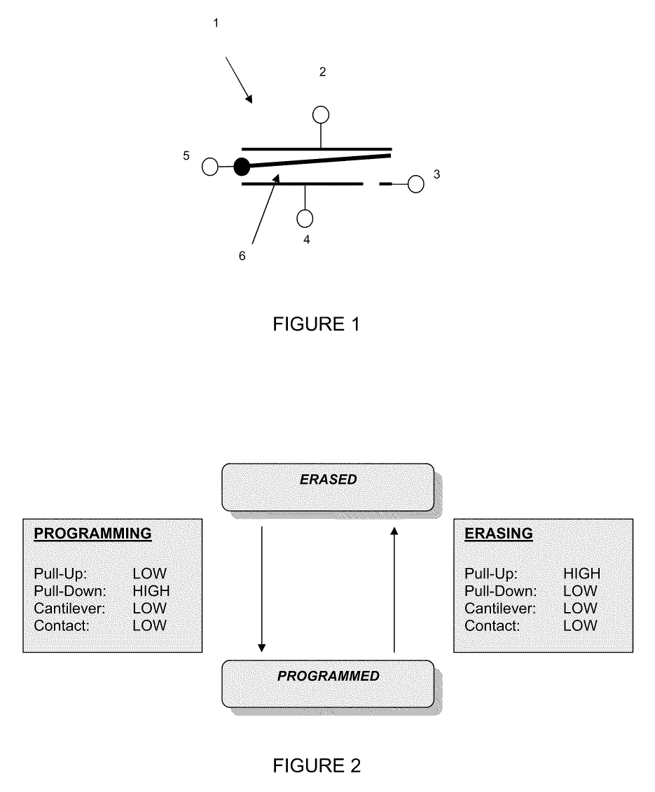

With reference to FIG. 1, a Multiple-Time Programmable (MTP) bitcell in accordance with the following embodiments of the present invention comprises a four-terminal cantilever device 1. The cantilever device 1 comprises a cantilever 6 which is positioned between a pull-up electrode 2 and a pull-down electrode 4. The proximal end of the cantilever 6 is connected to a cantilever electrode 5. The distal end of the electrode may freely move between the pull-up electrode 2 and a contact electrode 3. The electrodes are made of a suitable electrically conductive material. The pull-up electrode 2 is covered with an insulating material such that, when the cantilever 6 is brought into contact with the pull-up electrode 2, current is prevented from flowing therebetween.

When the cantilever 6 is in contact with either of the pull-up electrode 2 or the contact electrode 3, it is held in place via adhesion forces consisting of metal-to-metal bonding, Van der Waals forces and Casimir forces. These forces are collectively known as “stiction”. In order to move the electrode from one position to another, electrostatic forces are generated by the application of specific voltages to the various electrodes. These electrostatic forces overcome the stiction forces and move the cantilever from one position to another.

In one embodiment, the cantilever 6 may comprise a conductive material. In another embodiment, the cantilever 6 may comprise titanium nitride. In one embodiment, the cantilever 6 may consist of titanium nitride. In another embodiment, the cantilever 6 may comprise a metal. In one embodiment, the contact electrode 5 may comprise a conductive material. In another embodiment, the contact electrode 5 may comprise titanium nitride. In one embodiment, the contact electrode 5 may consist of titanium nitride. In another embodiment, the contact electrode 5 may comprise a metal. In one embodiment, the pull-down electrode 4 may comprise a conductive material. In another embodiment, the pull-down electrode 4 may comprise titanium nitride. In one embodiment, the pull-down electrode may consist of titanium nitride. In another embodiment, the pull-down electrode 4 may comprise a metal. In one embodiment, the pull-up electrode 2 may comprise a conductive material. In another embodiment, the pull-up electrode 2 may comprise titanium nitride. In one embodiment, the pull-up electrode 2 may consist of titanium nitride. In another embodiment, the pull-up electrode 2 may comprise a metal. In one embodiment, the conductive material for the pull-up electrode 2, the cantilever 6, the pull-down electrode 4 and the contact electrode 5 may be the same. In another embodiment, the conductive material for the pull-up electrode 2, the cantilever 6, the pull-down electrode 4 and the contact electrode 5 may be the different. In one embodiment, the pull-up electrode 2 may be coated with an insulating material. In another embodiment, the insulating material may comprise spin-on dielectric, a silicon oxide such as silicon dioxide, silicate glass, SiOC or combinations thereof.

Now, with reference to FIG. 2, the various states of the cantilever device 1 will now be described. As is clear from FIG. 2, the cantilever device 1 will be in an “erased” state when the cantilever 6 is in contact with the pull-up electrode 2. Conversely, the cantilever device 1 will be in a “programmed” state when the cantilever 6 is in contact with the contact electrode 3. In order to “erase” the cantilever device 1 (i.e., urge the cantilever 6 into the erased state), a voltage is applied between the cantilever electrode 5 and the pull-up electrode 2. Conversely, in order to “program” the cantilever device 1 (i.e., urge the cantilever 6 into the programmed state), a voltage is applied between the cantilever electrode 2 and the pull-down electrode 4.

When the cantilever 6 is programmed and comes into contact with the contact electrode 3, a current may run through the contact electrode 3, which may result in damage to the contact electrode 3 or the cantilever 6 and a subsequent loss of device operation. In order to avoid this, the flow of current should be prevented by breaking the current path before or upon contact. This is achieved by connecting the contact electrode to a transistor. During program or erase operations, this transistor can be switched off so there is no DC current path between the cantilever 6 and the contact electrode 3 when these components make contact.

Although the current path is broken, the contact electrode 3 of the device may still be damaged by a voltage applied across the contact electrode 3 and cantilever 6. In such a situation, as the cantilever 6 nears the contact electrode 3, the electric field becomes relatively powerful, which can result in electrostatic breakdown and can also lead to contact electrode 3 damage or an increase in stiction force. Devices which operate in such a way are said to be hot-switched. Conversely, devices which do not have a voltage applied across the cantilever electrode 5 and the contact electrode 3 when the cantilever device is programmed are said to be non-hot-switched.

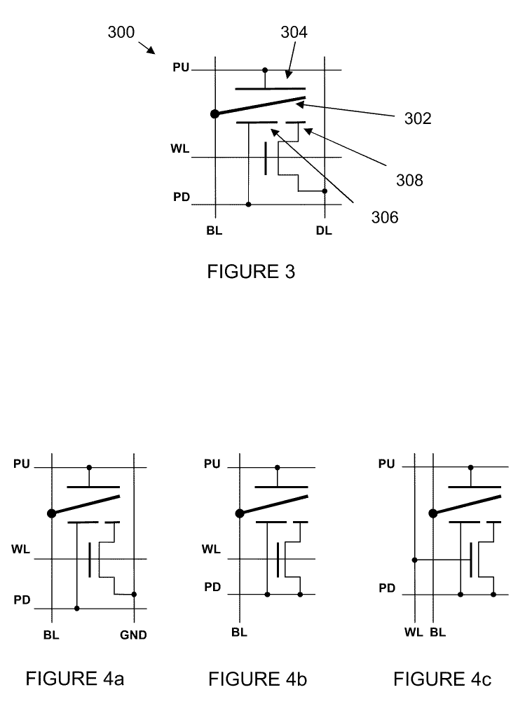

Now, with reference to FIG. 3, a first embodiment of the present invention will now be described. A memory bitcell 300 in accordance with the first embodiment comprises a cantilever device as described above. The pull-up electrode 304 is connected to the pull-up line PU, the pull-down electrode 306 is connected to the pull-down line PD, the cantilever electrode 302 is connected to the bitline BL and the contact electrode 308 is connected to the drain of an NMOS transistor. The source of the NMOS transistor is connected to the data line DL and the gate of the NMOS transistor is connected to the word line WL. It is to be understood that a PMOS transistor may be used instead of an NMOS transistor.

During a programming operation, the transistor is off and the state of the bitcell is determined by the voltage on the bitline BL, pull-up line PL and the pull-down line PD. During a read operation, the state of the bitcell 300 can be sensed by setting the word line WL to a read voltage and reading the current through the cantilever with a sense amp (not shown). This sense amp can be connected in several known ways, thereby sensing the current in the bitline BL, sensing the current in the data line DL or sensing the current in both the bitline BL and the data line DL using a differential sensing approach.

FIGS. 4a-4c show three alternate embodiments of the present invention. As can be seen, these embodiments of the present invention share the following two features. First, in order to program the bitcell, the bitline BL must run orthogonally to the programming line. As will be appreciated, in a hot-switched device, the programming line will be the pull-up PU line and in a non-hot-switched device, the programming line will be the pull-down PD line. Secondly, in order to read the state of any bitcell in a memory array, the word line WL runs orthogonal to the current sensing line.

FIG. 4a shows a first alternate embodiment where the data line DL is connected to a fixed ground. Accordingly, during the read cycle, the current can be sensed in the bitline BL. FIG. 4b shows a second alternate implementation where the transistor is connected to the pull-down line PD. This embodiment is possible because, as will be explained below, the pull-down line PD is grounded during a read procedure. In this embodiment, during a read cycle, the current can be sensed in the bitline BL. Dissimilarly, the current is not sensed in the pull-down line PD because the word line WL runs in parallel with the pull-down line PD. FIG. 4c shows a third alternate implementation where the transistor is also connected to the pull-down line PD. In this embodiment, however, the current is sensed in the pull-down line PD. Also, the current is not sensed in the bitline BL because the word line WL runs parallel with the bitline BL.

In all of the above embodiments, the program/erase behavior is not affected since the selection transistor is off during the program/erase operation. Thus, even if the voltage on the bitline BL or the pull-down line PD is high, a DC current prevented from running though the transistor. As will be appreciated, and as will be further explained below, depending on the drive signals applied to the various nodes, the bitcell can be hot-switched or non-hot-switched.

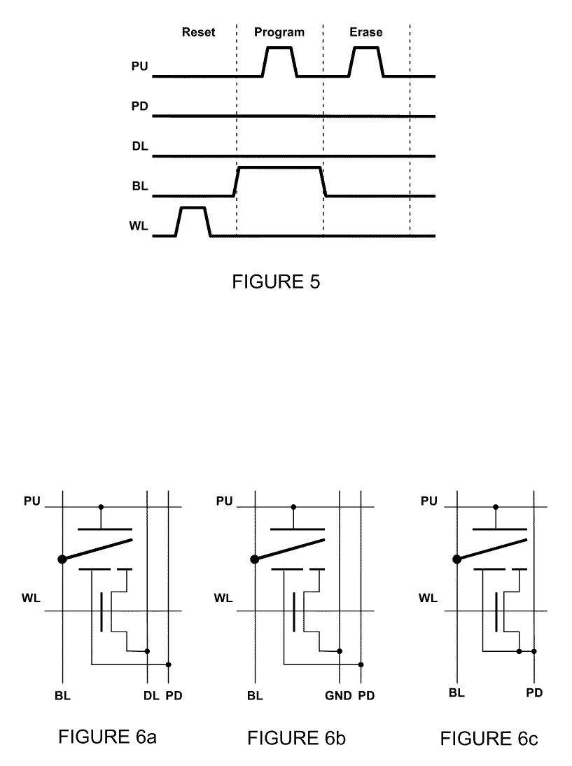

With reference to FIGS. 5 and 6a-6c, the operation of a hot-switched device in accordance with the present invention will now be described. In a hot-switched bitcell, the programming signal is applied to the pull-up electrode and a ground potential is applied to the pull-down electrode, as shown in FIG. 5. For a hot-switched device, the bitcell is programmed by setting the voltage on the bitline BL to HIGH. Once the cantilever lands on the contact electrode, the transistor, whose capacitance is in the sub-fF range, is quickly charged (in the order of picoseconds) to the programming voltage. Thus, for a very brief period of time, there is a current spike running through the cantilever contact, the bitcell in this embodiment being hot-switched. When the bitline BL voltage is subsequently reset to 0V, at the end of the programming cycle, there is another current spike. However, since the slope in the bitline BL voltage is much smaller than the RC-delay in the cantilever contact, this second current spike is much smaller.

As can also be seen from FIG. 5, the bitcell is erased by applying a low voltage to the bitline. During the erase operation, no voltage is applied across the contact electrode. Accordingly, current is prevented from flowing therethrough.

Alternate implementations of a hot-switched version of the present invention are shown in FIGS. 6a-6c. As can be seen, the orientation of the pull-down PD line has been rotated by 90°. In these embodiments, the bitline BL runs parallel to the pull-down line PD and orthogonal to the pull-up line PU. The signals required to program/erase the bitcells shown in FIGS. 6a-6c are the same as already shown in FIG. 5. However, the connection from the bitcell to the senseamp (not shown) will be different for each implementation.

In the device of FIG. 6a, the current can be sensed in either the bitline BL, the data line DL or in both using a known differential sensing approach. This is possible because the word line WL runs orthogonal to the bitline BL and the data line DL. In the device of FIG. 6b, the transistor is grounded and the current can be sensed in the bitline BL. In the device of FIG. 6c, the transistor is connected to the pull-down line PD and the current can be sensed in either the bitline BL, the pull-down line PD or in both using a known differential sensing approach. This is possible because the write line WL runs orthogonally to the bitline BL and the pull-down line PD. In all of the above hot-switched implementations, the pull-down line PD can also be connected to a fixed ground GND since the programming signals during the programming/erasing operations are applied to the pull-up line PU and during the read operation there is no need to apply a signal to the pull-down line PD.

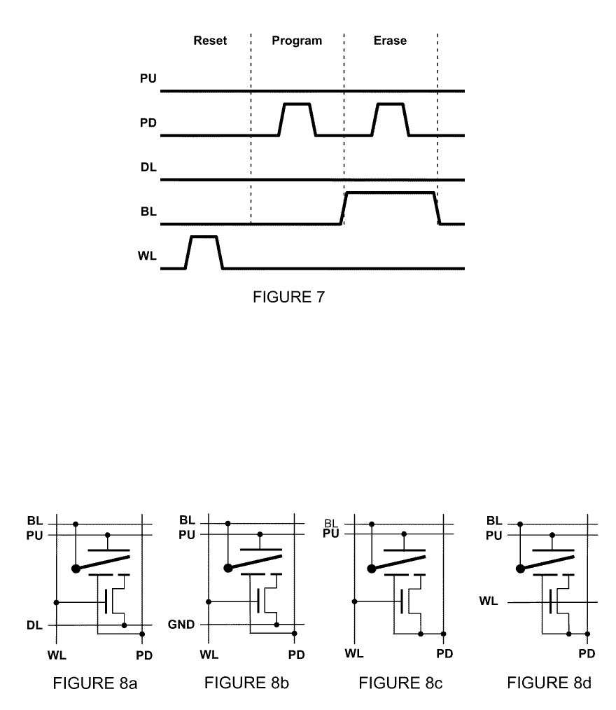

Now, with reference to FIGS. 7, 3 and 4a-4c, the operation of a non-hot-switched device in accordance with the present invention will now be described. In a non-hot-switched bitcell according to the present invention, the programming signal is applied to the pull-down electrode and a ground potential is applied to the pull-up electrode, as shown in FIG. 7.

In operation, the bitcell is programmed by applying a low voltage on the bitline BL. Since both the cantilever and the contact electrode are at ground potential during the programming operation, there is no current spike upon programming. Thus, the bitcell in the embodiment is said to be non-hot-switched. The bitcell is erased by setting the bitline BL HIGH. This will also charge the transistor capacitance through the closed cantilever switch and a current spike through the cantilever contact may occur. However, since the slope of the bitline voltage is much smaller than the RC-delay in the cantilever contact, this current spike is relatively small and the contact is not damaged.

Alternative implementations of the non hot-switched architectures are shown in FIGS. 8a-8d. In these implementations the orientation of the bitline BL, the data line DL and pull-down line PD has been rotated by 90°. The bitline BL runs parallel to the pull-up line PU and orthogonal to the pull-down line.

The signals required to program and erase the bitcells shown in FIGS. 8a-8d are those shown in FIG. 7. The connections of the sense amp to the bitcells are different for each of these implementations. In the device of FIG. 8a, the current can be sensed on either the bitline BL, the data line DL or both using a known differential sensing approach. This is possible because the write line WL runs orthogonal to the bitline BL and the data line DL. In the device of FIG. 8b, the transistor is always grounded and the current therefore is sensed in the bitline BL. In the device of FIG. 8c, the transistor is connected to the data line PD and the current can be sensed in the bitline BL. The current is not sensed in the pull-down line PD because the word line WL runs parallel with the pull-down line PD. In the device of FIG. 8d, the transistor is connected to the pull-down line PD and the current can be sensed in the pull-down line PD. The current is not sensed in the bitline BL because the word line WL runs parallel with the bitline BL. In all of these above non-hot-switched implementations, the pull-up line PU can also be connected to a fixed ground because the programming signals during programming/erasing operations are applied to the pull-down line PD and during reading operations there is no need to apply a signal to the pull-up line PU.

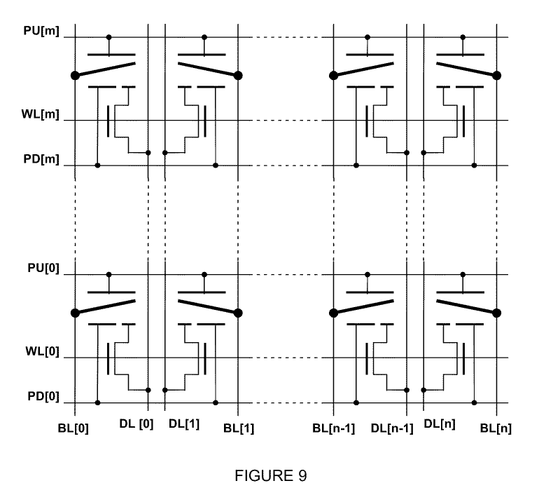

Now, with reference to FIGS. 9 to 11, a memory array in accordance with the present invention will now be described. Memory arrays are created by connecting rows or columns of bitcells together.

FIG. 9 shows a possible memory array comprising the bitcell design of FIG. 3 with the transistors connected to the data lines DL[0:n]. The memory array of FIG. 9 can be used in a hot-switched or non-hot-switched mode by applying the programming pulses either to the pull-up lines PU, as shown in FIG. 5, or the pull-down lines PD, as shown in FIG. 7. During a read operation, the current can be sensed in either the bitline BL, in the data line DL or in both, using known differential sensing approaches.

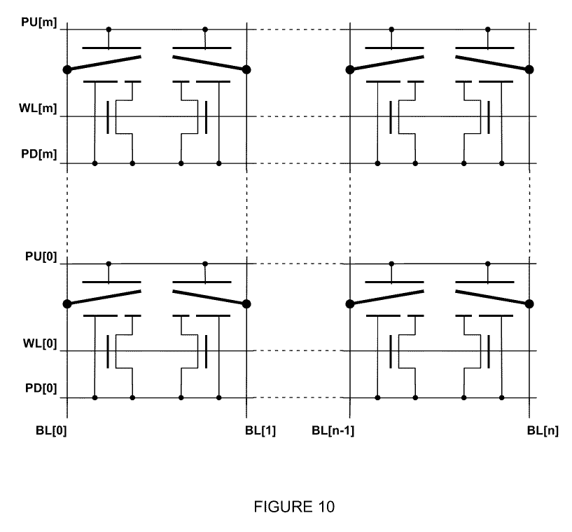

Similar memory architectures that support both hot-switched and non hot-switched operation can be generated by using the alternative implementations of FIGS. 4a-4c. For example, the memory architecture of FIG. 10 uses the bitcell implementation shown in FIG. 4b. During a read operation, the current in this case is sensed in the BL, because the pull-down lines PD run in parallel with the word lines WL. As will be appreciated, similar architectures using the other bitcell implementations of FIGS. 4a-4c can be created.

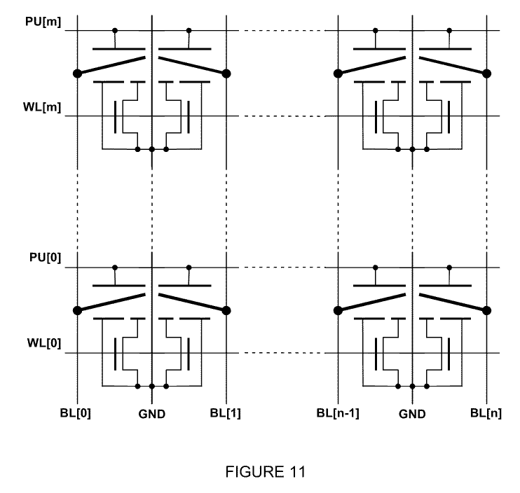

If the bitcell configurations of FIGS. 6a-6c are used, the resulting array operates as a hot-switched device. For example, the memory architecture shown in FIG. 11 uses the bitcell implementation of FIG. 6c with the pull-down lines PD connected to ground (GND). During a read operation, the current in this example is sensed in the bitline BL. Similar architectures using the bitcell implementations of FIG. 6a and FIG. 6b can also be generated.

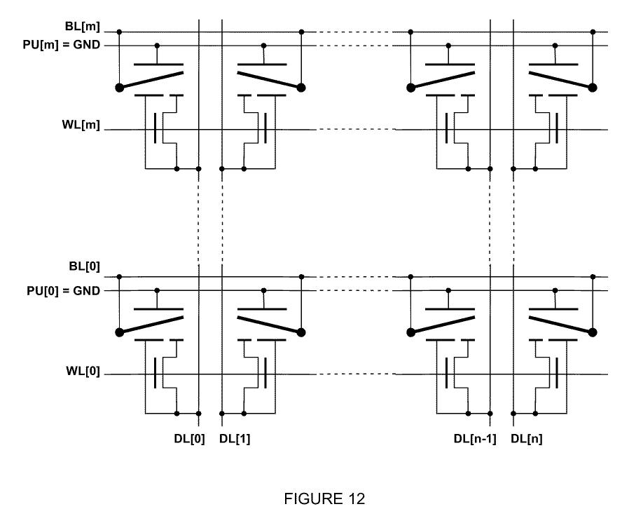

If the bitcell configurations of FIGS. 8a-8d are used, the resulting array operates as a non hot-switched device. For example, the memory architecture of FIG. 12 uses the bitcell implementation FIG. 8d with the pull-up lines PU connected to ground (GND). The programming signals are applied to pull-down PD/data lines DL. Because the word lines WL runs orthogonal to data lines DL and in parallel to the bitlines BL, the current can be sensed in the data lines DL during a read operation. Similar architectures using the other bitcell implementations of FIGS. 8a-8d can be generated.

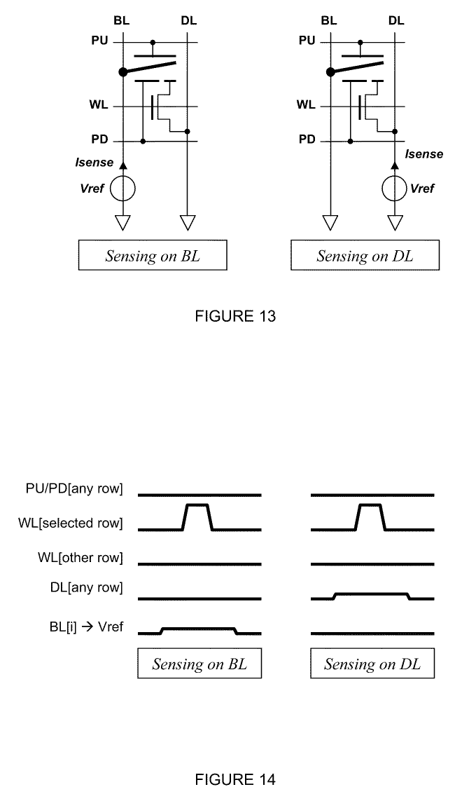

The state of a cell in the array can be sensed by applying a small voltage V_{ref} and sensing the current in either the bitlines BL or data lines DL, as shown in FIG. 13. The current running through the cantilever and contact electrode must be small in order not to damage the cantilever or contact electrode. A typical range for the reference voltage would be 50-200 mV. The timing of the various signals for the above examples is shown in FIG. 14. All pull-up PU and pull-down PD lines are kept at 0V and a small reference voltage is applied either to the bitlines BL or to the data line DL. Then, the selected row is activated by setting the word line WL high and the current flowing into the bitline is sensed with the sense-amps.

The main difference between these two read-out mechanisms is the mechanical effect the read-out has on the cantilevers. During the read procedure, the pull-up electrodes and pull-down electrodes are at ground potential. If the reference voltage is applied to the bitline BL, then the cantilevers in the selected column will all have this same potential. This is because, in most cases, the majority of the resistance of the switch will be determined by the contact interface between the cantilever and the contact electrode (i.e., there will be a minimal voltage drop across the actual cantilever). As a result, the cantilever will experience electrostatic forces in both the up and down direction.

Depending on the state of an individual bitcell, these forces have a different effect on the cantilever. If the cantilever is in the erased state, then the gap between the cantilever and the pull-up electrode is smaller than the gap between the cantilever and the pull-down electrode. As a result, the electrostatic forces urging the cantilever towards the pull-up electrode are larger than the electrostatic forces urging the cantilever towards the pull-down electrode. Consequently, the cantilever is pulled further towards the pull-up electrode.

Conversely, if the bitcell is in a programmed state, the cantilever is further pulled towards the pull-down electrode. If however the cantilever is in the freestanding state, the direction of the net force acting on the cantilever depends on the gap at the top and bottom of the cantilever and on the curvature of the cantilever. These parameters can be designed and controlled such that the net electrostatic force always pulls the cantilever upwards, thereby ensuring that a read operation does not accidentally close the cantilever and cause a read error.

From the above, it will be clear that the read operation does not change the state of the bitcell in that once a reference voltage is applied on the bitline BL, all cantilevers in the same column (including the non-selected cantilevers) will be at the same potential V_{ref}. All of these cantilevers will therefore experience a similar net electrostatic force pulling them closer to the nearest electrode.

If the reference voltage V_{ref} is applied on the data line DL in FIG. 13, the contact potential will near V_{ref} and the cantilever potential will near 0V. Since the pull-up PU electrode and pull-down PD electrode are also at 0V, the resulting electrostatic forces pulling on the cantilever will be insignificant. Also, in this example, reading a bitcell has no impact on the state of that bitcell. Moreover, none of the other cantilevers in the same column will experience a net electrostatic force. Therefore, the above example has a lower chance of resulting in a read error.

The timing of the various signals in the array during program and erase are shown in FIG. 5 (hot-switched operation) and in FIG. 7 (non hot-switched operation). In the following description of the operation of a circuit in accordance with the present invention, the programming line refers to the pull-up line PU for the hot-switched configuration and the pull-down line PD for the non-hot-switched configuration. When the voltage on the programming line is set HIGH, the state of the bitcell changes as follows.

A bitcell is programmed by applying a net electrostatic force towards the pull-down electrode. This is achieved as follows. First, the selection transistor is turned on for a short period of time by applying a pulse on the word line WL. This resets the voltage on the contact electrode to ground (GND). This step is optional and may not be required. Then, the bitline BL of the bitcell to be programmed is set to the appropriate value (HIGH for a hot-switched device and LOW for a non-hot-switched configuration) while the program line of the selected row is still LOW.

This action, which prepares the bitcell to be programmed, does not change the state of the bitcell because both the pull-up electrode and the pull-down electrode are still LOW. Even if the bitline BL voltage is HIGH, the cantilever will merely be pulled closer to the electrode it is already closest to, as explained above. The fact that the cantilever moves closer to one electrode and therefore that the electrostatic force between the cantilever and that electrode becomes stronger (while the electrostatic force towards the other electrode becomes weaker) introduces a hysteresis effect. This hysteresis effect allows flexibility in the design of the cantilever and electrode dimensions. In the next step, the programming line of the selected row is set HIGH. This will result in a net electrostatic force acting on the cantilever, urging it towards the programming-electrode and changes the bitcell state to the programmed state. Then, the programming line can be set to LOW again and the bitline BL can subsequently be set back to LOW (in the event that it was initially set HIGH).

Similarly, a bitcell is erased by applying a net electrostatic force towards the pull-up electrode. First, the selection transistor is turned on for a short period of time by applying a pulse on the word line WL. This resets the voltage on the contact electrode to ground (GND). This step is optional and may not be required. The bitline BL of the bitcell which is to be erased is set to the appropriate value (i.e., remains LOW for a hot-switched device and will be set HIGH for a non-hot-switched device) while the programming line of the selected row is still LOW. This action, which prepares the bitcell to be erased, does not change the current state of the bitcell because both the pull-up electrode and pull-down electrode are still at ground (GND). Even if the bitline voltage is HIGH, the cantilever will merely be pulled closer to the electrode it is already closest to. In the next step the programming line of the selected row is set HIGH. This will result in a net electrostatic force acting on the cantilever towards the pull-up electrode and will change the bitcell state to an erased state. Now, the programming line can be set to LOW again and the bitline can then be set back to LOW (in the event that it was initially set HIGH).

The bitcells are programmed and erased by charging up the bitlines and programming lines. The power required to do this is mainly determined by a transient effect. When the switch is closed, there is no DC current flowing through the transistor because the selection transistor is off. Therefore, the amount of power required to program or erase the memory is limited.

Once a voltage is applied on the programming line, the state of the bitcells in the selected row can change depending on the value of the bitline BL voltages. Bitcells in the non-selected rows will not change their state because the programming lines of these rows will remain set LOW (i.e., both the pull-up electrode and the pull-down electrode of the non-selected rows will be LOW). If a high voltage is applied to the bitline, the cantilevers connected to this bitline will experience a net electrostatic force pulling them closer towards the closest electrode. As a result, the state of these non-selected bitcells will not change.

It is therefore clear that the state of the bitcell is determined by the voltage on the bitline when the programming line is set HIGH. Other bitcells connected to the same programming line (i.e., in the same row of the array) will also experience a net electrostatic force which depends on the voltage on the bitlines BL of these bitcells. For instance, in the case of a non-hot-switched device, if a particular bitline BL is set LOW, then the bitcell of the selected row will be programmed and if a particular bitline BL is set HIGH, then the bitcell of the selected row will be erased. This means that if some bitcells in the selected row must remain in their current state, a further step must be taken to ensure this. There are several methods for avoid the accidental programming or erasing of these bitcells, as will now be described.

First the state of each bitcell in the selected row is read and then the bitlines of these bitcells are set to the appropriate voltage to avoid a change in state. This means that if a bitcell is in the programmed state, a low voltage is applied on the accompanying bitline and if a bitcell is in the erased state, a high voltage is applied on the accompanying bitline. Effectively these bitcells are re-programmed or re-erased with their existing state. This method will be effective for non-hot-switched devices. For hot-switched devices, the polarity of the voltage needs to be reversed. This ensures that a programmed cell stays programmed and an erased cell stays erased.

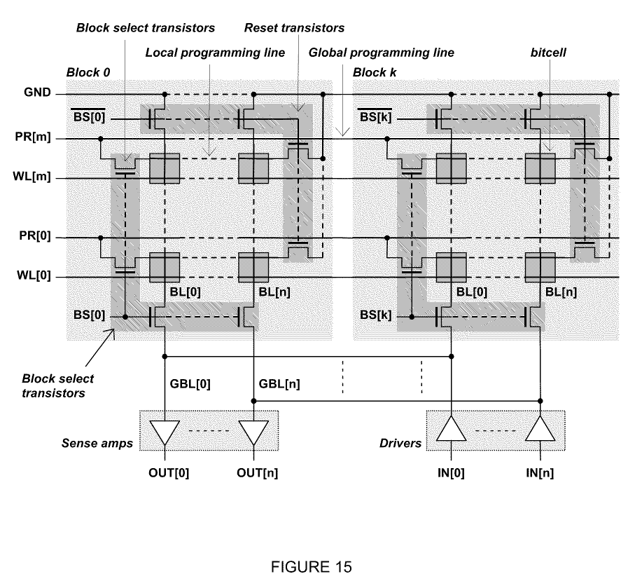

The disadvantage of this method is that a read-before-write needs to be applied and all bitcells which should remain in their current state need to be re-programmed or re-erased. If there are more columns in the array than sense amps, several read-cycles are required to get all the programmed values. Then, these values will need to be re-written in the columns. A block architecture, as shown in FIG. 15 can be used to limit this burden to a single read-cycle after which the appropriate values are applied to the bitlines.

Alternatively, the voltage applied to the other bitlines can be set to a holding voltage Vₕ. The value of this voltage is set such that even when the programming voltage is applied to the pull-up electrode or the pull-down electrode, there is only a small net electrostatic force pulling on the cantilever, thereby ensuring that the state of the bitcell is preserved. Preferably, this voltage is approximately equal to one half of the programming voltage.

Depending on the state of the cantilever, different effects may be achieved. If the cantilever is in the erased state, the gap between the cantilever and the pull-up electrode is smaller than the gap between the cantilever and the pull-down electrode. As a result, the electrostatic forces towards the top are larger than the electrostatic forces towards the bottom. Thus, the cantilever is pulled further towards the pull-up electrode. Similarly, if the cantilever is in the programmed state, the cantilever is pulled more intimate towards the pull-down electrode.

If however the cantilever is in a freestanding state, the direction of the net force acting on the cantilever depends on the gap at the top and bottom of the cantilever and on the curvature of the cantilever. These parameters can be designed and controlled such that the net electrostatic force always pulls the cantilever upwards. Consequently, the holding voltage does not close the cantilever switch and cause a program/erase error.

Because the force in one direction is always larger than the force in the other direction, due to the difference in the gap on both sides, there is a certain window in the holding voltage for which the above description will be valid, despite the holding voltage being less than ½ V_{prog} or more than ½ V_{prog}.

Because of the application of a hold voltage, there will be two electrostatic forces in both directions (pull-up and pull-down) and both forces are less (about 4 times in the case of ½ V_{prog}) than the force, when the full V_{prog} is applied on one side of the cantilever. By design, the resulting electrostatic force will be towards the current position of the cantilever. But even by imperfect design (different gap-size and non ideal ½ V_{prog}), the net result of these two smaller opposing electrostatic forces will be a lot smaller than the required electrostatic force to overcome the stiction at the contact or pull-off electrode. In case of a freestanding device, it needs to be designed such that the resulting electrostatic force is less than the force required to bend the cantilever to a programmed or erased state.

The disadvantage of this programming option is that this method requires a closer timing relation between the bitline and programming signals as the transition of signals should not result in a false programming event. It should be possible to keep the relation between these signals within a few nanoseconds within every bitcell, which should be sufficient to avoid false programming events.

In some applications, a bit-by-bit program/erase may not be required and data is written in bytes or words. An architecture that allows this is shown in FIG. 15. For the sake of clarity, data lines DL are not shown in FIG. 15. The block architecture of FIG. 15 applies to all of the shown memory architectures described above.

Each of these blocks has its own local-programming line connected with a block-select transistor to the global-programming line PR[i]. These programming lines are either the PU-lines in case of the hot-switched configuration or the PD-lines in case of the non hot-switched configuration. The bitlines BL[i] of each block will also pass through block-select transistors and connect to the global bitlines GBL[i]. The block is selected with a block-select signal BS[i]=HIGH. Upon read or program/erase, the block select transistors will connect the bitlines BL[i] of the selected block to the sense amps and also connect the local programming lines of the selected block to the global programming lines PR[j].

To program or erase bitcells, the appropriate voltages need to be applied to the global bitlines GBL[i] and all bitcells in the selected row of the selected block are programmed/erased in one cycle. When a block is not selected (i.e. BS[i]=0), the local programming lines as well as the bitlines are connected to ground (GND) to avoid undesired programming/erasing of bitcells. This is achieved by adding extra reset transistors to ground on the local programming lines and local bitlines. These transistors are activated when the block is not selected. This will ensure that all the bitcells in these blocks will remain in their programmed or erased state.

If only a few bits in the block need to be programmed and the remaining bits of the selected row must remain in their existing state, then a read-before-write scheme should be implemented. In this case, a single read cycle is required to read the state of all the bitcells of the selected block. At this point, the appropriate voltages can be applied to the bitlines, before the new values are programmed to the selected bitcells. The other bitcells of the selected row will be re-programmed or re-erased with their existing value.

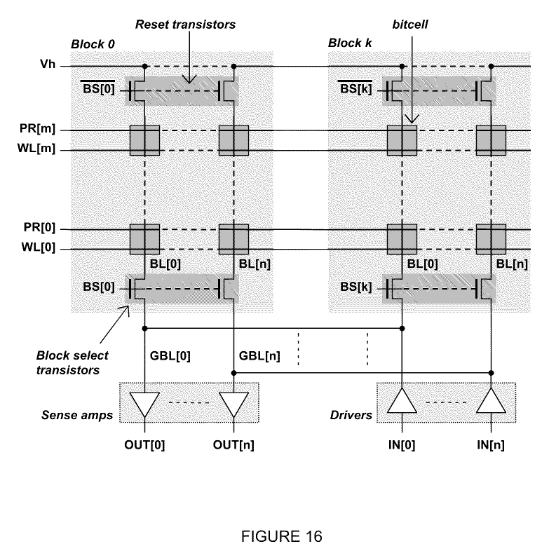

As will be appreciated, similar block architectures can be achieved by using the holding voltage method, as described above. In such an embodiment, there is no need for local programming lines and the architecture can be simplified. The resulting architecture is shown in FIG. 16. The reset transistors on top set the local bitlines to Vh when a block is not selected, thereby preventing the bitcells in the non-selected blocks from being programmed or erased. When a block is selected, the appropriate voltages can be applied to the bitlines in order to program or erase the bitcells of the selected row in the selected block.

While the foregoing is directed to embodiments of the present invention, other and further embodiments of the invention may be devised without departing from the basic scope thereof, and the scope thereof is determined by the claims that follow.

1. A non-volatile memory bitcell, comprising:
a pull-up electrode covered in electrically insulating material;
a pull-down electrode;
a contact electrode disposed adjacent the pull-down electrode; and
a cantilever electrode connected to a bi-stable cantilever positioned between the pull-up electrode and the contact electrode, the bi-stable cantilever movable between a position in contact with the contact electrode and a position in contact with the insulating material covering the pull-up electrode.

2. The non-volatile memory bitcell of claim 1, further comprising a transistor coupled to the contact electrode.

3. The non-volatile memory bitcell of claim 2, wherein an electrode of the transistor is coupled to a data line which is orthogonal to a word line, the word line is coupled to the gate electrode of the transistor and the word line is orthogonal to a bitline that is coupled to the cantilever electrode.

4. The non-volatile memory bitcell of claim 3, wherein a pull-down line that is coupled to the pull-down electrode is orthogonal to the bitline and parallel to the word line.

5. The non-volatile memory bitcell of claim 4, wherein the transistor is an NMOS transistor and the contact electrode is coupled to a drain of the NMOS transistor.

6. The non-volatile memory bitcell of claim 2, wherein the transistor is coupled to ground, the cantilever is coupled to a bitline that is orthogonal to a word line and the word line is coupled to the gate electrode of the transistor.

7. The non-volatile memory bitcell of claim 2, wherein the transistor is coupled to a pull-down line that is coupled to the pull-down electrode, the cantilever is coupled to a bitline that is orthogonal to a word line and the word line is coupled to the gate electrode of the transistor.

8. The non-volatile memory bitcell of claim 7, wherein the pull-down line is orthogonal to the word line.

9. The non-volatile memory bitcell of claim 2, wherein the transistor is coupled to a pull-down line that is coupled to the pull-down electrode, the cantilever is coupled to a bitline that is parallel to a word line, the word line is coupled to the gate electrode of the transistor and the word line is orthogonal to the pull-down line.

10. The non-volatile memory bitcell of claim 2, wherein the transistor is coupled to a data line that is orthogonal to a word line, the word line is coupled to the gate electrode of the transistor, a pull-down line is coupled to the pull-down electrode, the pull-down line is parallel to the word line and the cantilever is coupled to a bitline that is orthogonal to the word line.

11. The non-volatile memory bitcell of claim 2, wherein the transistor is coupled to ground, the cantilever is coupled to a bitline that is orthogonal to a word line, the word line is coupled to the gate electrode of the transistor and the pull-down electrode is coupled to a pull-down line that is parallel to the word line.

12. The non-volatile memory bitcell of claim 2, wherein the transistor is coupled to a data line that is orthogonal to a word line, the word line is coupled to the gate electrode of the transistor and the cantilever is coupled to a bitline that is orthogonal to the word line.

13. A memory array, comprising:
a plurality of non-volatile memory bitcells that each comprise:
a pull-up electrode covered in electrically insulating material;
a pull-down electrode;
a contact electrode disposed adjacent the pull-down electrode;
a cantilever electrode connected to a bi-stable cantilever positioned between the pull-up electrode and the contact electrode, the bi-stable cantilever movable between a position in contact with the contact electrode and a position in contact with the insulating material covering the pull-up electrode; and
a transistor coupled to the contact electrode, wherein the drain electrode of the transistor is coupled to the contact electrode.

14. The memory array of claim 13, further comprising:
a first pull-down line coupled to the pull-down electrode of a first non-volatile memory bitcell and a second non-volatile memory bitcell;
a second pull-down line coupled to a third non-volatile memory bitcell;
a first bitline coupled to the first non-volatile memory bitcell and the third non-volatile memory bitcell;
a second bitline coupled to the second non-volatile memory bitcell;
a first data line coupled to the first non-volatile memory bitcell and the third non-volatile memory bitcell; and
a second data line coupled to the second non-volatile memory bitcell, wherein at least one of the first bitline, the second bitline, the first data line, and the second data line are orthogonal to a word line that is coupled to the gate electrode of the transistor.

15. The memory array of claim 14, wherein the first data line and the second data line are each coupled to a transistor of a corresponding non-volatile memory bitcell.

16. The memory array of claim 13, further comprising:
a first pull-down line coupled to the pull-down electrode of a first non-volatile memory bitcell, a second non-volatile memory bitcell, the transistor of the first non-volatile memory bitcell, and the transistor of the second non-volatile memory bitcell;
a second pull-down line coupled to a third non-volatile memory bitcell and the transistor of the third non-volatile memory bitcell;
a first bitline coupled to the first non-volatile memory bitcell and the third non-volatile memory bitcell; and
a second bitline coupled to the second non-volatile memory bitcell, wherein both the first bitline and the second bitline are orthogonal to a word line that is coupled to the gate electrode of the transistor.

17. The memory array of claim 16, wherein the first pull-down line is parallel to the word line.

18. The memory array of claim 13, further comprising:
a first bitline coupled to a first non-volatile memory bitcell and a second non-volatile memory bitcell;
a second bitline coupled to a third non-volatile memory bitcell, wherein the transistor of each non-volatile memory bitcell is coupled to ground and both the first bitline and the second bitline are orthogonal to a word line that is coupled to the gate electrode of the transistor.

19. The memory array of claim 13, further comprising:
a first bitline coupled to a first non-volatile memory bitcell and a second non-volatile memory bitcell;
a second bitline coupled to a third non-volatile memory bitcell;
a first data line coupled to the first non-volatile memory bitcell and the third non-volatile memory bitcell; and
a second data line coupled to the second non-volatile memory bitcell, wherein both the first data line and the second data line are orthogonal to a word line that is coupled to the gate electrode of the transistor and the first bitline and the second bitline are parallel to the word line.

20. A method of detecting the state of a non-volatile memory array bitcell, the non-volatile memory bitcell comprising a pull-up electrode covered in electrically insulating material, a pull-down electrode, a contact electrode disposed adjacent the pull-down electrode, a cantilever electrode connected to a bi-stable cantilever positioned between the pull-up electrode and the contact electrode, the bi-stable cantilever movable between a position in contact with the contact electrode and a position in contact with the insulating material covering the pull-up electrode, and a transistor coupled to the contact electrode, wherein a drain electrode of the transistor is coupled to the contact electrode the method comprising:
applying a voltage to either a bitline coupled to the cantilever or a data line coupled to the drain electrode of the transistor; and
sensing the current in either the bitline or the data line.
